(19) United States
(12) Patent Application Publication
(10) Pub. No.: US 2008/0303134 A1
(43) Pub. Date: Dec. 11, 2008

(54) Semiconductor package and method for fabricating the same

(75) Inventors: Chun-Yuan Li, Taichung Hsien (TW); Hsiao-Jen Hung, Taichung (TW); Chin-Huang Chang, Taichung Hsien (TW); Jeng-Yuan Lai, Taichung Hsien (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/156,875

(22) Filed: Jun. 5, 2008

(30) Foreign Application Priority Data
Jun. 6, 2007 (TW) 096120262

(51) Int. Cl. H01L 23/52; H01L 21/02

(52) U.S. Cl. 257/691; 438/124; 257/E21.002; 257/E23.079

(57) ABSTRACT

A semiconductor package and a method for fabricating the same are disclosed, which includes: providing a carrier board, forming a plurality of metal bumps on the carrier board, forming a metal layer on the carrier board to encapsulate the metal bumps, having at least one semiconductor chip electrically connected to the metal layer, then forming an encapsulant on the carrier board to encapsulate the semiconductor chip, and next removing the carrier board and the metal bumps to correspondingly form a plurality of grooves on surface of the encapsulant, wherein bottom and sides of the grooves are covered with the metal layer to allow electroconductive components to be effectively positioned in the grooves and completely bonded with the metal layer.

### BACKGROUND OF THE INVENTION

1. Field of the Invention

The invention generally relates to a semiconductor package and method for fabricating the same, and more specifically, to a semiconductor package without a chip carrier and method for fabricating the same.

2. Description of Related Art

There is a great variety of conventional semiconductor packages that use lead frames as chip carriers. Taking a Quad Flat Non-leaded (QFN) semiconductor package as an example, its main feature is that it has no external terminal, namely, it does not have an external terminal for electrically connecting to external devices, such as those in a conventional quad flat package (QFP), thereby being capable of reducing semiconductor package size.

However, limited by encapsulant thickness, the entire height of conventional QFN packages with leadframe cannot be further reduced to follow the trend of developing thinner and lighter semiconductor devices. Therefore, the industry has developed a type of semiconductor package free of a chip carrier, which is much thinner and lighter than conventional leadframe packages.

Referring to FIG. 1, which shows a semiconductor package free of a chip carrier disclosed in U.S. Pat. No. 5,830,800. A plurality of electroplated solder pads 12 are formed on a copper plate (not shown in FIG. 1), and then a chip 13 is disposed on the copper plate and electrically connected to the electroplated solder pads 12 via a plurality of bonding wires 14. A package molding process is performed to form an encapsulant 15, and the copper plate is subsequently removed by etching to expose the electroplated solder pads 12. Afterwards, a solder mask layer 11 is formed to define positions of the electroplated solder pads 12, such that solder balls 16 can be mounted on the electroplated solder pads 12, thereby forming a semiconductor package without a chip carrier. Related prior arts are also disclosed in U.S. Pat. Nos. 6,770,959, 6,989,294, 6,933,594, and 6,872,661.

In the aforesaid semiconductor package free of a chip carrier, a solder mask layer must be first formed to define the positions of the electroplated solder pads, for mounting of the solder balls on the electroplated solder pads. However, after the copper plate has been removed by etching, in the case of a batch-type process, the entire encapsulant structure is in a form of an array, and then warpage is likely to occur in the encapsulant structure. This is is difficult to effectively and precisely define openings in the solder mask layer corresponding to the electroplated solder pads. On the other hand, in the case of a singular-type process, processes of coating, exposure, and development of the solder mask are performed on a relatively smaller area, and thus fabrication efficiency is lowered and fabrication cost is increased. Further, if the positions of the electroplated solder pads are not defined by the solder mask layer, it is difficult to have solder balls precisely positioned on the electroplated solder pads, and in turn causing problems such as shift and delamination of solder balls on the electroplated solder pads during a reflow process.

In view of the aforesaid disadvantage, U.S. Pat. No. 6,072,239 discloses a semiconductor package free of a chip carrier and method for fabricating the same, as shown in FIGS. 2A to 2D. Referring to FIG. 2A, a copper plate 20 is provided, a resist layer 21 is formed on the copper plate 20, and a plurality of apertures 210 formed through the resist layer 21, for defining electroplating positions on the resist layer 21, such that a plurality of metal solder pads 22 are formed in the apertures 210 by electroplating. Referring to FIG. 2B, the resist layer 21 is removed, and then the copper plate 20 is semi-etched by using the metal solder pads 22 as an etching mask, so as to form relatively higher and lower surfaces on the copper plate 20. Referring to FIG. 2C, a semiconductor chip 23 is mounted on the relatively lower surface of the copper plate 20 and electrically connected to the metal solder pads 22 on the relatively higher surface of the copper plate 20 via bonding wires 24, and then an encapsulant 25 is formed on the copper plate 20 to encapsulate the semiconductor chip 23 and the bonding wires 24. Referring to FIG. 2D, the copper plate 20 is removed by etching to form a plurality of grooves 250 on surface of the encapsulant 25, and the metal solder pads 22 are located on bottom of the grooves 250. Namely, the metal solder pads are relatively recessed inside the encapsulant 25, such that a plurality of solder balls 26 can be mounted on the metal solder pads 22 recessed inside the encapsulant 26 and be effectively positioned.

However, in the aforesaid fabrication method, the etching depth is not easy to be controlled in the semi-etching process of the copper plate. In other words, it is difficult to form grooves having the same depth in the encapsulant, and consequently, the solder balls mounted on the metal solder pads at bottom of the grooves may have different heights. Furthermore, since eutectic structures are only formed between the bottoms of the solder balls and the metal solder pads, cracks are more likely to occur to the solder balls compared with and stress concentration at corners of the openings of the grooves, (as shown in FIG. 3A). In addition, since the metal solder pads are electroplating layers each having a thickness of about 0.5 to 5 μm and are in contact with the encapsulant only at bottoms of the grooves, adhesion force among each other is obviously limited, and delamination among the metal solder pads and the encapsulant are likely to occur due to solder ball stress as shown in FIG. 3B.

Therefore, the problem to be solved here is to provide a semiconductor package free of a chip carrier and method for fabricating the same, which are capable of effectively positioning solder balls, avoiding problems such as cracks on solder balls and delamination on metal solder pads due to concentrated stress of solder balls, thereby enhancing fabrication process efficiency without the need to apply a solder mask layer, improving solder ball quality and decreasing the fabrication cost.

### SUMMARY OF THE INVENTION

In view of the disadvantages of the prior art mentioned above, it is an objective of the present invention to provide a semiconductor package free of a chip carrier and a method for fabricating the same.

It is another objective of the present invention to provide a semiconductor package and a method for fabricating the same, which are capable of effectively defining positions of solder pads for mounting of solder balls thereon.

It is a further objective of the present invention to provide a semiconductor package and a method for fabricating the same, which are capable of defining positions of solder pads without the need to apply a solder mask layer, thereby simplifying fabrication process as well as lowering cost.

It is still another objective of the present invention to provide a semiconductor package and a method for fabricating the same, which are capable of avoiding delamination problems between solder pads and encapsulant.

It is still another objective of the present invention to provide a semiconductor package and a method for fabricating the same, which are capable of preventing solder balls from crack due to concentrated stress applied on the solder balls.

To achieve the aforementioned and other objectives, a method for fabricating a semiconductor package is disclosed according to the present invention, which comprises: providing a carrier board and forming a plurality of metal bumps on the carrier board; forming a metal layer on the carrier board to encapsulate the metal bumps; electrically connecting at least one semiconductor chip to the metal layer; forming an encapsulant on the carrier board to encapsulate the semiconductor chip; removing the carrier board and the metal bumps to correspondingly form a plurality of grooves on surface of the encapsulant, thereby exposing the metal layer in the grooves; and mounting a plurality of electroconductive components in the grooves.

The method for fabricating the metal bumps and the metal layer comprises: providing a metal carrier board made of metal, forming a first resist layer on the metal carrier board, and also forming a plurality of first openings in the first resist layer; performing an electroplating process so as to form a plurality of metal bumps in the first openings; removing the first resist layer; forming a second resist layer on the metal carrier board, and forming a plurality of second openings in the second resist layer to expose the metal bumps, wherein the second openings are larger than the first openings in size; performing an electroplating process so as to form a metal layer in the second openings, the metal layer encapsulating the metal bumps; and removing the second resist layer.

In addition, the metal layer is formed on bottom and sides of the grooves, and protrudes from the bottom of the grooves. Alternatively, the metal layer is formed on sides and bottom of the grooves of the encapsulant, and the metal layer has extended portions formed on encapsulant surface around openings of the grooves, thereby increasing bonding area between electroconductive components and the metal layer, and consequently enhancing bonding strength between the electroconductive components and the metal layer.

By means of the foresaid fabrication method, a semiconductor package is further disclosed according to the present invention, which comprises: an encapsulant having a plurality of grooves formed on surface thereof; a metal layer covering bottom and sides of the grooves; a semiconductor chip embedded in the encapsulant and electrically connected to the metal layer; and a plurality of electroconductive components mounted in the grooves and electrically connected to the metal layer.

In view of the above, the present invention mainly comprises forming a plurality of metal bumps on a carrier board, forming a metal layer on the carrier board to encapsulate the metal bumps so as to electrically connect at least one semiconductor chip to the metal layer, forming an encapsulant on the carrier board to encapsulate the semiconductor chip, next removing the carrier board and the metal bumps so as to form a plurality of grooves on surface of the encapsulant with bottom and sides of the grooves being covered with the metal layer. Thereafter, a plurality of electroconductive components is mounted in the grooves, thereby obtaining a semiconductor package of the present invention. Accordingly, depth of the grooves formed on surface of the encapsulant can be precisely controlled and defined by height of the metal bumps, thereby avoiding unstable height of solder balls mounted in subsequent process caused by uncontrollable etching depth during semi-etching of the copper plate as in prior art. Besides, the grooves can effectively position the electroconductive components, thereby avoiding complicated fabrication process and high cost of prior art that positions solder balls via solder mask. In addition, the electroconductive components contact the metal layer of the present invention via both bottom and sides of the grooves, thereby providing sufficient eutectic structure and consequently enhancing bonding strength between the electroconductive components and the metal layer. Furthermore, the metal layer contacts the encapsulant via bottom and sides of the grooves, thereby making the metal layer be efficiently attached to the encapsulant and consequently avoiding delamination problem. Furthermore, since the electroconductive components contact with the encapsulant through the metal layer around openings of the grooves, cracks of the electroconductive components due to concentrated stress is reduced.

### BRIEF DESCRIPTION OF DRAWINGS

The present invention can be more fully understood by reading the following detailed description of the preferred embodiments, with reference made to the accompanying drawings, wherein:

FIG. 1 is a diagram of a semiconductor package free of a chip carrier disclosed by U.S. Pat. No. 5,830,800;

FIGS. 2A to 2D are diagrams showing a fabrication method of a semiconductor package without a chip carrier disclosed in U.S. Pat. No. 6,072,239;

FIGS. 3A and 3B are diagrams showing defects of cracks of solder balls and delamination of the metal layer of a semiconductor package without a chip carrier disclosed by U.S. Pat. No. 6,072,239;

FIGS. 4A to 4G are diagrams showing a semiconductor package and a method for fabricating the same according to a first embodiment of the present invention;

FIGS. 5A to 5G are diagrams showing a semiconductor package and a method for fabricating the same according to a second embodiment of the present invention; and

FIG. 6 is a diagram of a semiconductor package according to a third embodiment of the present invention.

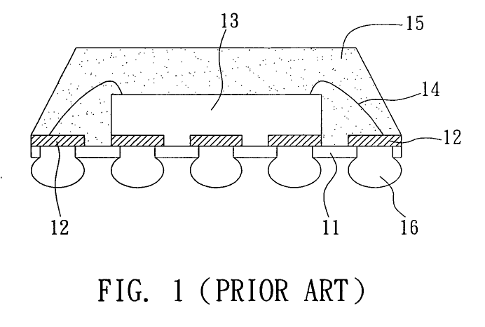

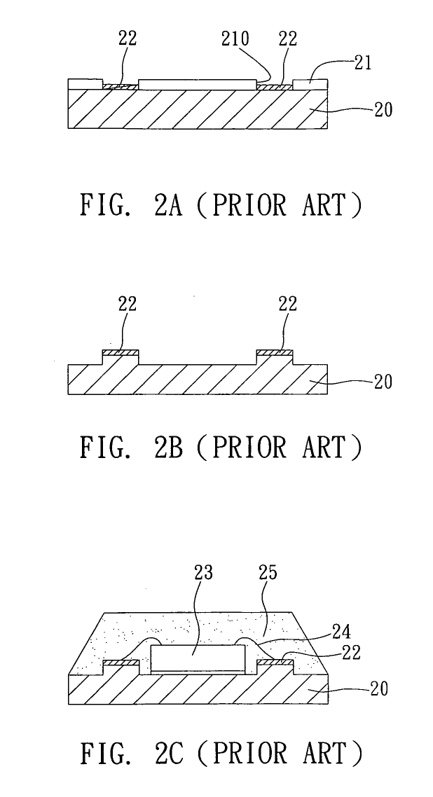

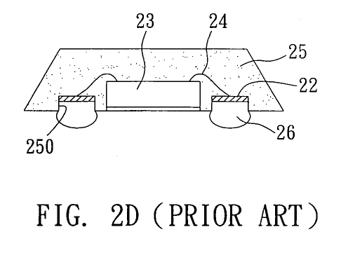

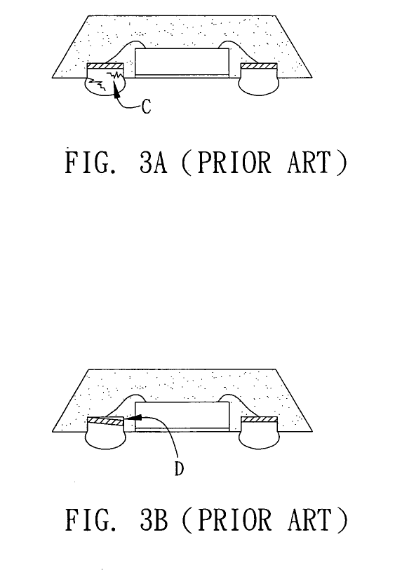

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

### First Embodiment

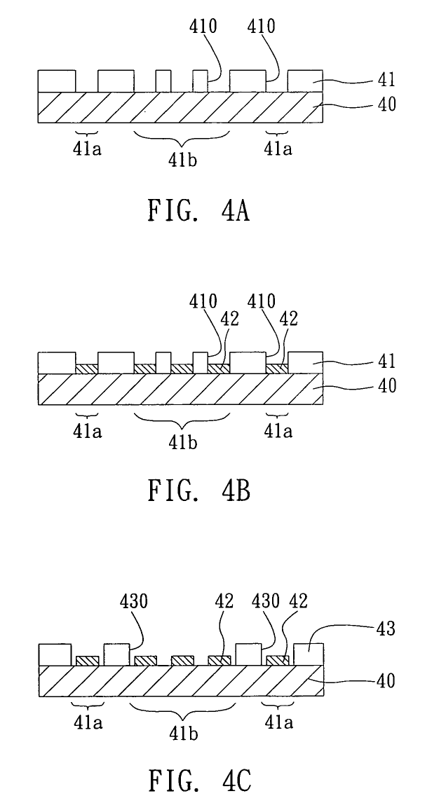

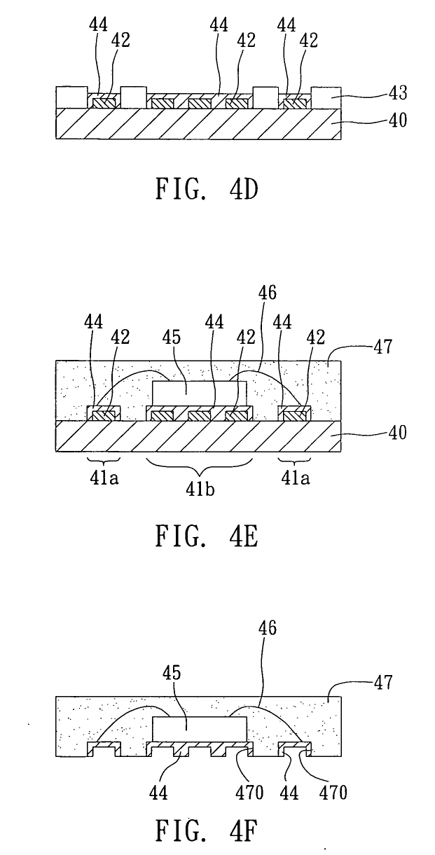

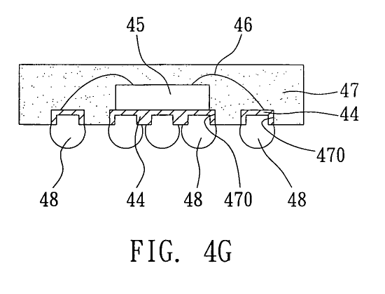

Referring to FIGS. 4A to 4G, which are diagrams showing a semiconductor package and a method for fabricating the same according to a first embodiment of the present invention.

As shown in FIG. 4A, a carrier board 40 made of a metal material such as a copper plate is first provided, a first resist layer 41 is formed to cover surface of the metal carrier board 40, and a plurality of first openings 410 are formed in the first resist layer 41, for defining positions of terminals 41a to be electrically connected to a semiconductor chip, as well as position of a die pad 41b for subsequent mounting of a semiconductor chip.

As shown in FIG. 4B, an electroplating process is performed so as to form a plurality of metal bumps 42 made of, for example, copper in the first openings 410.

As shown in FIG. 4C, the first resist layer 41 is removed, a second resist layer 43 is formed to cover the metal carrier board 40, and a plurality of second openings 430 are formed in the second resist layer 43 to expose the metal bumps 42 for defining positions of the terminals 41a and position of the die pad 41b again. The second openings 430 are larger than the first openings 410 in size, such that the metal bumps 42 are completely exposed from the second resist layer 43.

As shown in FIG. 4D, an electroplating process is performed to form a metal layer 44 in the second openings 430, wherein the metal layer 44 encapsulates the metal bumps 42. The metal layer is made of gold/palladium/nickel/palladium (Au/Pd/Ni/Pd), gold/nickel/gold (Au/Ni/Au), or gold/copper/gold (Au/Cu/Au).

As shown in FIG. 4E, the second resist layer 43 is removed, a semiconductor chip 45 is mounted on the metal layer 44 corresponding to the position of the die pad 41b, and electrically connected to the metal layer 44 corresponding to the positions of the terminals 41a via bonding wires 46, and then an encapsulant 47 is formed on the metal carrier board 40 to encapsulate the semiconductor chip 45 and the bonding wires 46.

As shown in FIG. 4F, the metal carrier board 40 and the metal bumps 42 are removed at the same time by etching, so as to form a plurality of grooves 470 on surface of the encapsulant 47 at positions where the metal carrier board 40 and the metal bumps 42 are removed. Meanwhile, at least bottoms and sides of the grooves 470 are covered with the metal layer 44.

As shown in FIG. 4G, a plurality of electroconductive components 48 (such as solder balls) are mounted in the grooves 470. The electroconductive components 48 are effectively bonded with and electrically connected to the metal layer 44 via the bottoms and sides of the grooves 470.

The electroconductive components 48 mounted on the metal layer 44 corresponding to the positions of the terminals 41a are used for transmitting semiconductor chip signals, while the electroconductive components 48 mounted on the metal layer 44 corresponding to the position of the die pad 41b are used for grounding the semiconductor chip or conducting heat.

Besides, in the fabrication process of the present invention, the semiconductor chip can also be mounted directly on the metal carrier board without the process of forming metal bumps and metal layer on the position of the die pad. Also, the semiconductor chip can further be electrically connected to the metal layer by means of flip chip.

By means of the aforesaid fabrication method, a semiconductor package is further disclosed according to the present invention, which comprises: an encapsulant 47 with a plurality of grooves 470 formed on surface thereof; a metal layer 44 covering bottom and sides of the grooves 470; a semiconductor chip 45 embedded in the encapsulant 47 and electrically connected to the metal layer 44; and a plurality of electroconductive components 48 mounted in the grooves 470 and electrically connected to the metal layer 44.

In view of the above, the semiconductor package and method for fabricating the same, according to the present invention, mainly comprises: forming a plurality of metal bumps on a carrier board first, and then forming a metal layer on the carrier board to encapsulate the metal bumps; electrically connecting at least one semiconductor chip to the metal layer, and forming an encapsulant on the carrier board to encapsulate the semiconductor chip; removing the carrier board and the metal bumps, so as to form a plurality of grooves on surface of the encapsulant at positions where the carrier board and the metal bumps are removed, and covering bottoms and sides of the grooves with the metal layer that previously covers the metal bumps; and mounting a plurality of electroconductive components in the grooves, thereby obtaining a semiconductor package of the present invention.

Accordingly, depths of the grooves formed on the surface of the encapsulaant can be precisely controlled and defined by height of the metal bumps, thereby preventing unstable heights of solder balls mounted in subsequent process caused by uncontrollable etching depth during semi-etching of the copper plate as found in the prior art. Moreover, the grooves can effectively position the electroconductive components, thereby avoiding complicated fabrication process and high cost observed in the prior art in which solder balls are positioned via solder mask. In addition, the electroconductive components are in contact with the metal layer via bottom and sides of the grooves, thereby providing a sufficient eutectic structure and consequently enhancing bonding strength between the electroconductive components and the metal layer. Furthermore, the metal layer are in contact with the encapsulant via the bottoms and sides of the grooves, thereby allowing the metal layer to be efficiently attached to the encapsulant and consequently avoiding delamination problem. Furthermore, since the electroconductive components are in contact with the encapsulant through the metal layer surrounding the openings of the grooves, cracks of the electroconductive components due to concentrated stress can be reduced.

### Second Embodiment

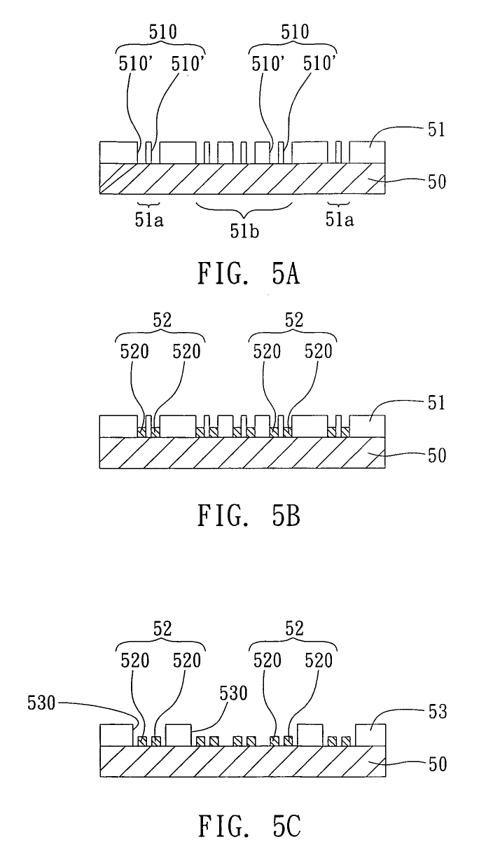

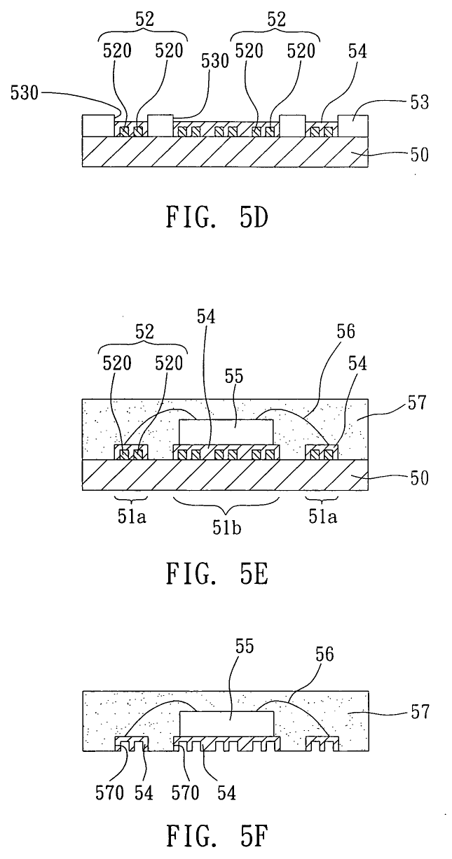

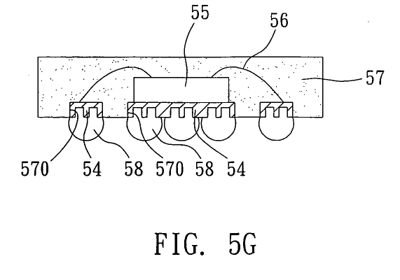

Referring to FIGS. 5A to 5G, which are diagrams showing a semiconductor package and method for fabricating the same according to a second embodiment of the present invention.

The semiconductor package and the method for fabricating the same of the present embodiment are substantially similar to the first embodiment, and the main difference is that each metal bump formed on the metal carrier board comprises a plurality of cylinders, and a metal layer is formed to encapsulate the metal bumps with a plurality of cylinders, such that when the metal carrier board and the metal bumps are subsequently removed, a plurality of grooves comprising protrusive metal layer are formed on surface of encapsulant, thereby increasing the contact area and enhancing bonding strength between the metal layer and the electroconductive components subsequently mounted in the grooves.

As shown in FIG. 5A, a metal carrier board 50 is prepared, and a first resist layer 51 is formed on surface of the metal carrier board 50 with a plurality of first openings 510 formed therein for defining positions of terminals 51a to be electrically connected to a semiconductor chip as well as position of a die pad 51b for subsequent mounting of a semiconductor chip. In the present embodiment, each of first openings 510 comprise a plurality of smaller apertures 510′.

As shown in FIG. 5B, an electroplating process is performed to form a plurality of electroconductive cylinders 520 in the smaller apertures 510′ of the first openings 510. In other words, a plurality of metal bumps 52 comprising a plurality of electroconductive cylinders 520 are formed in the first openings 510.

As shown in FIG. 5C, the first resist layer 51 is removed, and a second resist layer 53 is formed on the metal carrier board 50 with a plurality of second openings 530 formed therein for completely exposing the metal bumps 52 comprising a plurality of electroconductive cylinders 520.

As shown in FIG. 5D, an electroplating process is performed to form a metal layer 54 in the second openings 530, wherein the metal layer 54 encapsulates the metal bumps 52 comprising a plurality of electroconductive cylinders 520.

As shown in FIG. 5E, the second resist layer 53 is removed, a semiconductor chip 55 is mounted on the metal layer 54 corresponding to the position of the die pad 51b and electrically connected to the metal layer 54 corresponding to the positions of the terminals 51a via bonding wires 56. Next, an encapsulant 57 is formed on the metal carrier board 50 to encapsulate the semiconductor chip 55 and the bonding wires 56.

As shown in FIG. 5F, the metal carrier board 50 and the metal bumps 52 comprising a plurality of electroconductive cylinders 520 are removed at the same time by etching so as to form a plurality of grooves 570 on surface of the encapsulant 57 at positions where the carrier board and the metal bumps are removed, wherein, the metal layer 54, which previously covers the metal bumps 52 comprising a plurality of electroconductive cylinders is now formed on bottom and sides of the grooves 570 and also protrudes from bottom of the grooves 570.

As shown in FIG. 5G, a plurality of electroconductive components 58 such as solder balls is mounted in the grooves 570, which is effectively mounted on and electrically connected to the metal layer 54 located on bottom and sides of the grooves 570 and protruding from bottoms of the grooves 570.

### Third Embodiment

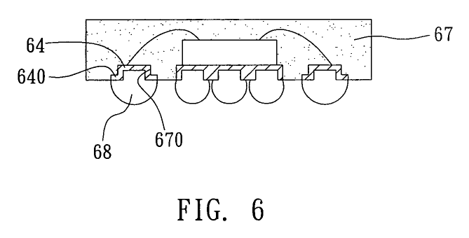

Referring to FIG. 6, which is a diagram of a semiconductor package according to a third embodiment of the present invention.

The semiconductor package of the present embodiment is mostly similar to the aforesaid first and second embodiments, and the main difference is that after the metal bumps are formed on the metal carrier board and before the metal layer is formed to encapsulate the metal bumps, the second openings of the second resist layer are increased in size, such that extended portions 640 of the metal layer 64 can be formed when the metal layer 64 is formed on the metal carrier board. Therefore, after the processes such die attachment, wire bonding, package molding, removal of the metal carrier board and metal bumps are performed subsequently, the metal layer 64 is formed on the bottoms and the sides of the grooves 670 on surface of the encapsulant 67. Meanwhile, the extended portions 640 of the metal layer 64 are formed on surface of the encapsulant 67 around openings of the grooves 670, thereby increasing the contact area between the metal layer 64 and the electroconductive components 68.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for fabricating a semiconductor package, comprising the steps of:
providing a carrier board and forming a plurality of metal bumps on the carrier board;
forming a metal layer on the carrier board to encapsulate the metal bumps;
electrically connecting at least a semiconductor chip to the metal layer;
forming an encapsulant on the carrier board to encapsulate the semiconductor chip;
removing the carrier board and the metal bumps to form a plurality of grooves on surface of the encapsulant at positions where the carrier board and the metal bumps are removed, thereby exposing the metal layer in the grooves; and
mounting a plurality of electroconductive components in the grooves.

2. The method of claim 1, wherein the method for fabricating the, metal bumps and the metal layer comprises:
providing a metal carrier board made of metal, forming a first resist layer on the metal carrier board, and also forming a plurality of first openings in the first resist layer;
performing an electroplating process to form a plurality of metal bumps in the first openings;
removing the first resist layer;
forming a second resist layer on the metal carrier board, and forming a plurality of second openings in the second resist layer to expose the metal bumps, wherein the second openings are larger than the first openings in size;
performing an electroplating process so as to form a metal layer in the second openings and have the metal layer encapsulate the metal bumps; and
removing the second resist layer.

3. The method of claim 1, wherein the metal layer defines positions of a plurality of terminals to be electrically connected to the semiconductor chip and a position of a die pad for mounting of the semiconductor chip.

4. The method of claim 3, wherein the electroconductive components mounted on the metal layer corresponding to the positions of the terminals are used for transmitting semiconductor chip signals, and the electroconductive components mounted on the metal layer corresponding to the position of the die pad are used for grounding the semiconductor chip or conducting heat.

5. The method of claim 1, wherein the semiconductor chip is mounted on the metal layer or the metal carrier board in the fabrication process.

6. The method of claim 1 wherein, the metal layer is made of one selected from gold/palladium/nickel/palladium (Au/Pd/Ni/Pd), gold/nickel/gold (Au/Ni/Au), and gold/copper/gold (Au/Cu/Au).

7. The method of claim 1, wherein each of the metal bumps is formed with a plurality of cylinders, and a metal layer is formed to encapsulate the metal bumps with a plurality of cylinders.

8. The method of claim 7, wherein method for fabricating the metal bumps and the metal layer comprises:
providing a metal carrier board made of metal, forming a first resist layer on the metal carrier board with a plurality of first openings formed therein, each of the first openings comprising a plurality of small sized apertures;
performing an electroplating process so as to form a plurality of electroconductive cylinders in the plurality of apertures of the first openings, thereby forming a plurality of metal bumps with a plurality of electroconductive cylinders in the first openings;
removing the first resist layer;
forming a second resist layer on the metal carrier board with a plurality of second openings formed therein for completely exposing the metal bumps with a plurality of electroconductive cylinders;
performing an electroplating process so as to form a metal layer in the second openings, and allowing the metal layer to encapsulate the metal bumps with a plurality of electroconductive cylinders; and
removing the second resist layer.

9. The method of claim 8, further comprising: removing the metal carrier board and the metal bumps with a plurality of electroconductive cylinders by etching, thereby forming a plurality of grooves on surface of the encapsulant, wherein the metal layer is formed on a plurality of bottoms and sides of the grooves, and protrudes from the bottoms of the grooves.

10. The method of claim 1, wherein the metal layer further comprises a plurality of extended portions covering the surface of the encapsulant surrounding the the grooves.

11. The method of claim 1, wherein, the semiconductor chip is electrically connected to the metal layer by one of wire bonding and flip chip.

12. A semiconductor package, comprising:
an encapsulant with a plurality of grooves formed on a surface thereof;
a metal layer covering a plurality of bottoms and sides of the grooves;
a semiconductor chip embedded in the encapsulant and electrically connected to the metal layer; and
a plurality of electroconductive components mounted in the grooves and electrically connected to the metal layer.

13. The semiconductor package of claim 12, wherein positions of a plurality of terminals to be electrically connected to the semiconductor chip and a position of die pad for mounting of the semiconductor chips are defined on the metal layer.

14. The semiconductor package of claim 13, wherein the electroconductive components mounted on the metal layer corresponding to the positions of terminals are used for transmitting semiconductor chip signals, and the electroconductive components mounted on the metal layer corresponding to the position of die pad are used for grounding the semiconductor chip or conducting heat.

15. The semiconductor package of claim 12, wherein the metal layer is made of one selected from the group consisting of gold/palladium/nickel/palladium (Au/Pd/Ni/Pd), gold/nickel/gold (Au/Ni/Au), and gold/copper/gold (Au/Cu/Au).

16. The semiconductor package of claim 12, wherein the metal layer is formed on the bottoms and sides of the grooves, and the metal layer protrudes from bottoms of the grooves.

17. The semiconductor package of claim 12, wherein the metal layer further comprises a plurality of extended portions formed on the surface of the encapsulant surrounding the grooves.

18. The semiconductor package of claim 12, wherein the semiconductor chip is electrically connected to the metal layer by one of wire bonding and flip chip.
